(19) United States
(12) Patent Application Publication
(10) Pub. No.: US 2014/0084754 A1
(43) Pub. Date: Mar. 27, 2014

(54) THIN FILM PIEZOELECTRIC DEVICE

(71) Applicant: TDK CORPORATION, Tokyo (JP)

(72) Inventors: Kazuhiko MAEJIMA, Tokyo (JP); Katsuyuki KURACHI, Tokyo (JP); Hitoshi SAKUMA, Tokyo (JP); Yasuhiro AIDA, Tokyo (JP); Yoshitomo TANAKA, Tokyo (JP)

(73) Assignee: TDK CORPORATION, Tokyo (JP)

(21) Appl. No.: 13/624,572

(22) Filed: Sep. 21, 2012

(51) Int. Cl. H01L 41/04; H01L 41/187

(52) U.S. Cl. CPC H01L 41/04; H01L 41/1873
USPC 310/367

(57) ABSTRACT

A thin film piezoelectric device according to the present invention includes a potassium sodium niobate-based piezoelectric thin film having an average crystal grain diameter of 60 nm or more and 90 nm or less, and a pair of electrode films configured to hold the piezoelectric thin film therebetween.

### BACKGROUND OF INVENTION

1. Technical Field

The present invention relates to a thin film piezoelectric device using a thin film piezoelectric material.

2. Background Art

When piezoelectric thin films are formed, crystallinity of films is controlled for achieving good piezoelectric characteristics. In order to realize high crystallinity, piezoelectric thin films are generally epitaxially grown on a single crystal substrate.

General methods for producing piezoelectric thin films include dry methods such as an ion plating method, a sputtering method, an electron beam evaporation method, and a MOCVD method (metal-organic chemical vapor deposition method), and wet methods such as a sol-gel method and a MOD method (metal-organic decomposition method).

Patent Literature 1 discloses an underlayer of a piezoelectric thin film, the underlayer being formed by a sputtering method. The c-axis orientation of the piezoelectric thin film is enhanced by using the underlayer having a smaller a-axis lattice constant than that of the piezoelectric thin film, resulting in enhancement of the piezoelectric characteristics of the piezoelectric thin film.

Patent Literature 2 discloses an alkali niobate-based piezoelectric thin film composed of crystal grains the majority of which have a columnar structure having a longer length in the thickness direction than that in the planar direction of a substrate and which have an average crystal grain diameter of 0.1 μm or more and 1 μm or less in the planar direction of the substrate in order to realize a high piezoelectric constant.

Patent Literature 3 discloses that a dielectric thin film is formed by a MOCVD method and then annealed in an atmosphere of oxidizing gas containing ozone to decrease defects in a network structure of the dielectric thin film, and consequently, a leakage current is decreased.

### PATENT LITERATURE

[PTL 1] Japanese Unexamined Patent Application Publication No. 11-026296

[PTL 2] Japanese Unexamined Patent Application Publication No. 2008-159807

[PTL 3] Japanese Unexamined Patent Application Publication No. 10-182300

### SUMMARY OF INVENTION

As described above, in order to realize practical piezoelectric characteristics of an alkali niobate-based piezoelectric thin film, the average crystal grain diameter is required to be controlled in a proper range.

However, with a larger crystal grain diameter, when oxygen deficiencies occur in grain boundaries formed in the thickness direction (perpendicular to an electrode film), the grain boundaries serve as current paths, increasing the risk of increasing a leakage current between electrode films. FIG. 2A is a schematic view illustrating a section of an alkali niobate-based piezoelectric thin film in which a leakage current is increased by an average crystal grain diameter larger than a proper range, and FIG. 2B illustrates an actually observed image.

This problem is a matter of great concern for manufacture of a thin film piezoelectric device and reliability thereof. As described above, a generally used countermeasure is to anneal a piezoelectric thin film after deposition thereof, but even when a dielectric thin film is formed by the sputtering method and then annealed, some extent of effect is obtained, but it is difficult to eliminate oxygen deficiencies in all grain boundaries in the film. Therefore, annealing after film formation is not a satisfactory countermeasure for decreasing a leakage current between electrode films.

The present invention has been achieved in consideration of the problem and is aimed at making it possible to enhance the reliability of a thin film piezoelectric device by decreasing a leakage current between electrode films without deterioration in piezoelectric characteristics of a potassium sodium niobate-based piezoelectric thin film (hereinafter referred to as a “KNN thin film”).

A thin film piezoelectric device according to the present invention includes a potassium sodium niobate-based piezoelectric thin film (KNN thin film) which has an average crystal grain diameter of 60 nm or more 90 nm or less, and a pair of electrode layers configured to hold the piezoelectric thin film therebetween. When the KNN thin film formed by crystal growth has an average crystal grain diameter within this range, a leakage current between electrode films formed on and below the piezoelectric thin film in the thin film piezoelectric device can be decreased. The potassium sodium niobate-based piezoelectric thin film refers to a thin film having a composition represented by the basic chemical formula (NaₓK₁₋ₓ)NbO₃ (0<x1) and, if required, containing various additives at the A site where an alkali metal is present and the B site where Nb is present.

Here, the average crystal grain diameter according to the present invention is defined. Specifically, the average crystal grain diameter is calculated by image analysis of an image obtained by observing a surface of the piezoelectric thin film with a scanning electron microscope (hereinafter referred to as “SEM”) within a field of view at an image magnification of 5000 times. The diameter of each crystal grain is determined by approximating the shape as a circular shape. The average of the approximate crystal grain diameters is considered as the average crystal grain diameter (refer to FIG. 4).

Further, the piezoelectric thin film according to the present invention preferably has a structure in which a section in a direction perpendicular to the electrode films contains a portion where a plurality of grains are present in the thickness direction of the piezoelectric thin film, and a ratio of total sectional area of the grains constituting the portion where the plurality of grains are present is 50% or more of the whole sectional area of the piezoelectric thin film.

Here, the section is a surface obtained by cutting, with a machine or focused ion beam (hereinafter referred to as “FIB”), a laminate including the piezoelectric thin film in the thickness direction of the piezoelectric thin film, and a broken-out surface thereof is observed with SEM or a transmission electron microscope (hereinafter referred to as “TEM”) at an image magnification of 10000 times. The expression “a portion where a plurality of grains are present in the thickness direction of the piezoelectric thin film” represents a portion where at least two particles are deposited in the thickness direction as shown in FIGS. 3A and 3B. In addition, “the total sectional area of the grains constituting the portion where a plurality of grains are present” represents a total of sectional areas of grains A to V shown in FIG. 3A or sectional areas of grains A to I shown in FIG. 3B. FIG. 3C shows an actual TEM image.

The piezoelectric thin film of the present invention preferably contains Mn (manganese). When the thin film contains Mn, a leakage current can be decreased, and high piezoelectric characteristic −d31 can be achieved.

In addition, the piezoelectric thin film of the present invention preferably contains at least three elements of Li (lithium), Sr (strontium), Ba (barium), Zr (zirconium), and Ta (tantalum). When the thin film contains these elements, a leakage current can be decreased, and high piezoelectric characteristic −d31 can be achieved.

According to the present invention, the average crystal grain diameter of crystal grains which constitute a potassium sodium niobate-based piezoelectric thin film is adjusted in a predetermined range, and thus both the two important characteristics for a thin film piezoelectric device, i.e., improved piezoelectric characteristics and decreased leakage current between electrode films, can be satisfied.

### BRIEF DESCRIPTION OF DRAWINGS

FIG. 1 is a drawing of a configuration of a thin film piezoelectric device according to the present invention.

FIG. 2A is a schematic drawing of a sectional structure of a piezoelectric thin film having high crystallinity.

FIG. 2B is an image of a transmission electron microscope (TEM) of the sectional structure.

FIGS. 3A and 3B are each a schematic drawing of a sectional structure of a potassium sodium niobate-based piezoelectric thin film according to the present invention.

FIG. 3C is an image of a transmission electron microscope (TEM) of the sectional structure.

FIG. 4 is a drawing illustrating the definition of an average crystal grain diameter according to the present invention.

### DESCRIPTION OF EMBODIMENTS

A preferred embodiment of the present invention is described in detail below with reference to the drawings.

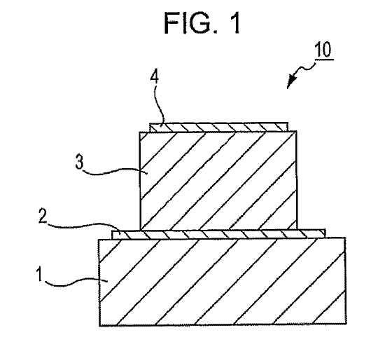

FIG. 1 illustrates a configuration of a thin film piezoelectric device 100 according to an embodiment of the present invention.

A substrate 1 is composed of single crystal silicon, sapphire, magnesium oxide, or the like, and single crystal silicon is particularly preferred from the viewpoint of cost and handleability in a process. The thickness of the substrate 1 is generally 10 to 1000 μm.

A lower electrode film 2 is formed on the substrate 1. As a material, Pt (platinum) and Rh (rhodium) are preferred. The forming method is a vapor deposition method or a sputtering method. The thickness is preferably 50 to 1000 nm.

A piezoelectric thin film 3 is formed on the lower electrode film 2. The piezoelectric thin film 3 is a potassium sodium niobate-based piezoelectric thin film having an average crystal grain diameter of 60 nm or more and 90 nm or less.

With an average crystal grain diameter of less than 60 nm, the piezoelectric characteristic −d31 is decreased to be lower than a value satisfactory for practical use of a thin film piezoelectric device, while with an average crystal grain diameter exceeding 90 nm, a leakage current between electrode films is increased to be higher than an upper limit for practical use of a thin film piezoelectric device.

A section of the piezoelectric thin film 3 in a direction perpendicular to the electrode films contains a portion where a plurality of grains are present in the thickness direction of the piezoelectric thin film 3, and a ratio of total sectional area of the grains constituting the portion where the plurality of grains are present is preferably 50% or more, more preferably 70% or more, of a total sectional area of the piezoelectric thin film 3. When the ratio of total sectional area of the portion where the plurality of grains are present in the thickness direction of the piezoelectric thin film 3 to the total sectional area of the film is within the above-described range, grain boundaries between the electrode films are complicated to increase the length of the grain boundaries, thereby decreasing a leakage current between the electrode films.

The piezoelectric thin film 3 preferably contains Mn (manganese). In this case, the leakage current of the thin film piezoelectric device 10 can be decreased, and higher piezoelectric characteristic −d31 can be achieved.

The piezoelectric thin film 3 preferably contains at least three elements of Li (lithium), Sr (strontium), Ba (barium), Zr (zirconium), and Ta (tantalum). When the thin film 3 contains these elements, the leakage current can be decreased, and higher piezoelectric characteristic −d31 can be achieved.

The thickness of the piezoelectric thin film 3 is not particularly limited and, for example, can be about 0.5 μm to 10 μm.

Next, an upper electrode film 4 is formed on the piezoelectric thin film 3. The material is preferably Pt or Rh which the same as the lower electrode film 2. The thickness is preferably 50 nm to 1000 nm.

Then, a laminate including the piezoelectric thin film 3 is patterned by photolithography and dry etching or wet etching, and finally the substrate 1 is cut to produce the thin film piezoelectric device 10. The substrate 1 may be removed from the thin film piezoelectric thin film 10, producing a thin film piezoelectric thin film including only the laminate. In addition, after the laminate is patterned, a protective film may be formed using polyimide or the like.

A method for evaluating the piezoelectric thin film 3 according to the embodiment of the present invention is as follows.

(1) Calculation of average crystal grain diameter:

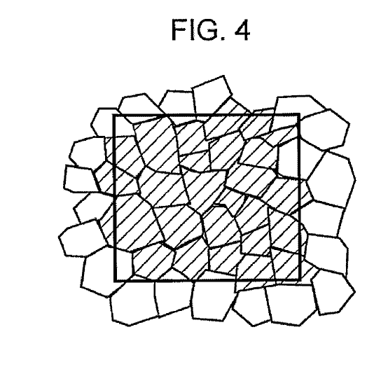

A surface of the piezoelectric thin film 3 after formation is observed with a scanning electron microscope (hereinafter referred to as “SEM”) within a field of view at an image magnification of 5000 times, followed by image analysis of the resultant image. The diameter of each crystal grain is determined by approximating the shape as a circular shape. The average of the approximate crystal grain diameters is considered as the average crystal grain diameter (refer to FIG. 4).

(2) Calculation of ratio of area in which a plurality of grains are present in the thickness direction of the piezoelectric thin film 3:

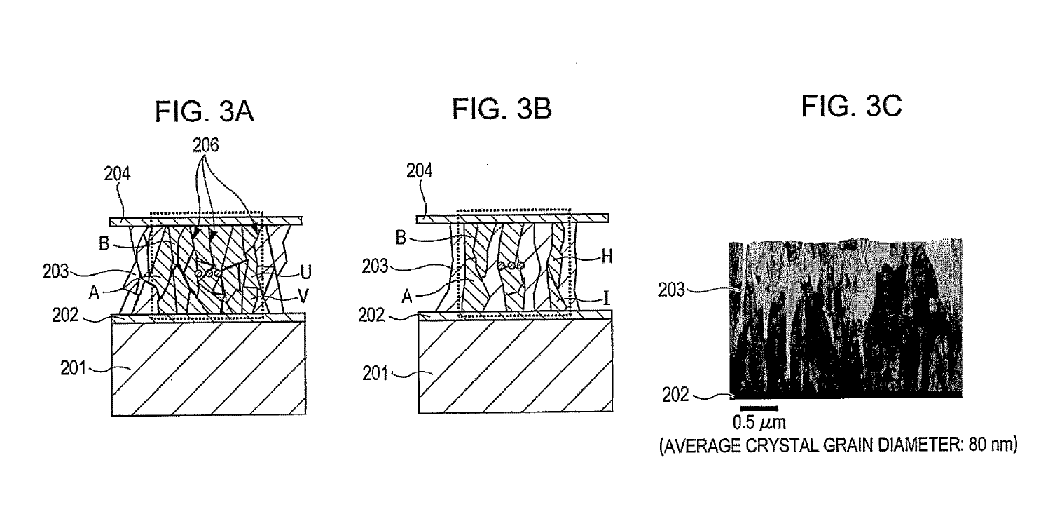

After the upper electrode film 4 is formed on the piezoelectric thin film 3, the piezoelectric thin film 3 is cut in the thickness direction of the piezoelectric thin film 3 with a machine or focused ion beam (hereinafter referred to as “FIB”) and a cut surface is observed with SEM or a transmission electron microscope (hereinafter referred to as “TEM”) at an image magnification of 10000 times. The total sectional area of crystal grains in the portion where the plurality of grains are present in the thickness direction of the piezoelectric thin film 3 is determined, and the total sectional area is divided by the total area of the section within the observation range (refer to FIGS. 3A and 3B).

(3) Measurement of leakage current density between electrode films:

The substrate 1 is cut into a size of 5 mm×20 mm to produce the thin film piezoelectric device 10, which is then measured by applying DC±20 V between the upper and lower electrode films 2 and 4 thereof. A ferroelectric evaluation system TF-1000 (manufactured by aixACCT Corporation) is used as an evaluation apparatus. The voltage application time is 2 seconds.

(4) Measurement of piezoelectric constant −d31:

Voltages of 3 Vₚ₋ₚ and 20 Vₚ₋ₚ at 700 Hz are applied between the upper and lower electrode films 2 and 4 of the thin film piezoelectric device 10, and a displacement at the tip of the thin film piezoelectric device 10 is measured with a laser Doppler vibrometer and an oscilloscope.

The piezoelectric constant −d31 can be determined by calculation according to the following expression (1):

$${d}_{31} ≅ - \frac{{h}_{s}^{2}}{3 {L}^{2}} \frac{{s}_{11 , p}}{{s}_{11 , s}} \frac{δ}{V} \qquad Expression ( 1 )$$

hₛ: thickness of Si substrate [400 μm], S_{11,p}: elastic compliance of KNN thin film [1/104 GPa], S_{11,s}: elastic compliance of Si substrate [1/160 GPa], length of drive portion [13.5 mm], δ: displacement, V: applied voltage

### Embodiment 1

A lower electrode film 2 is formed by crystal growth on a substrate 1 composed of single crystal silicon to form an underlayer of a piezoelectric thin film 3 (KNN thin film). The lower electrode film 2 is a Pt film and has a thickness of 50 to 1000 nm. The formation method is a sputtering method, and the film is formed under heating of the substrate. 1 at 500° C.

Then, the piezoelectric thin film 3 (KNN thin film) is formed using a (K, Na)NbO₃ sputtering target. The formation method is a sputtering method, and like the lower electrode film 2, the piezoelectric thin film 3 is formed under a condition where the substrate 1 is at a high temperature.

The substrate temperature is set to 520° C. to 460° C. At a substrate temperature of 520° C. or less, crystal growth is inhibited, resulting in a decrease in average crystal grain diameter of the piezoelectric thin film 3. At a set temperature of 460° C. or more, the average crystal grain diameter of the piezoelectric thin film 3 can be prevented from being excessively decreased, and deterioration in the piezoelectric constant −d31 can be prevented.

A smaller average crystal grain diameter enables deposition of a plurality of crystal grains in the thickness of the piezoelectric thin film 3. This is schematically shown in FIGS. 3A and 3B, in which grain boundaries of grains are complicated between electrode films, increasing the total length of the grain boundaries between the electrode films.

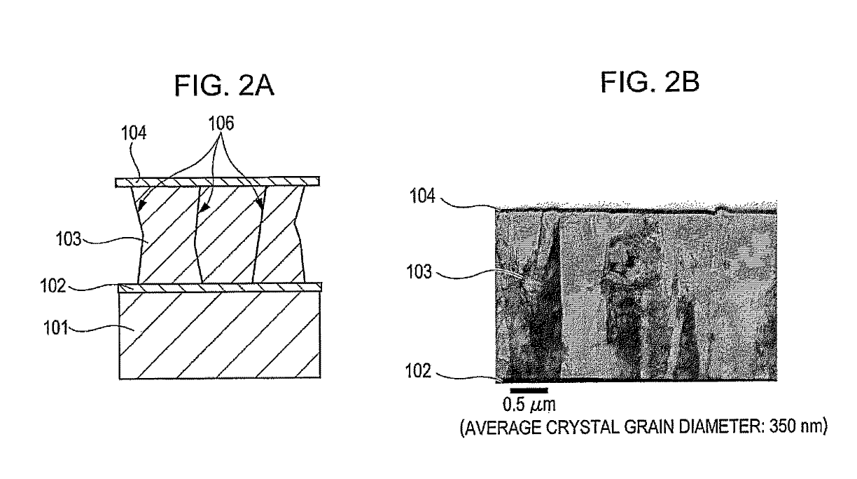

The inventors of the present invention suppose the following formation mechanism of a leakage path. A main cause for the leakage path lies in oxygen deficiencies in grain boundaries. The oxygen deficiencies are partially produced by causes, such as heat history, an oxygen partial pressure during film deposition, film thickness, amounts of additives, etc., not uniformly distributed in all grain boundaries. As the total length of grain boundaries increases, the ratio of positions where oxygen deficiencies are present to the total length of grain boundaries decreases, resulting in a decrease in leakage path. Assuming that the incidence rate of a leakage path due to one grain boundary is A %, and the number of crystal grains deposited in the thickness direction is N, the risk of causing a continuous leakage path by the crystal grains is A^{N}%. On the other hand, as shown in FIG. 2A, with higher crystallinity, the number of crystal grains deposited between the electrode films is 1, and thus the risk of causing a leakage path due to grain boundaries is A %. Because it is essential that A>A^{N}, deposition of a plurality of crystal grains in the thickness direction has the effect of decreasing a leakage current between the electrode films.

However, as described above, the piezoelectric characteristic −d31 is decreased by excessively decreasing the average crystal grain diameter. Therefore, it is necessary to realize a decrease in leakage current while maintaining piezoelectric characteristics required for the thin film piezoelectric device 10 by controlling the average crystal grain diameter in an appropriate range.

Next, the average crystal grain diameter in a surface of the piezoelectric thin film 3 (KNN thin film) is measured by the above-described method.

Then, an upper electrode film 4 is formed on the piezoelectric thin film 3 by the sputtering method. Like the lower electrode film 2, the material is preferably a Pt film. The thickness is 50 to 1000 nm.

Next, a laminate including the piezoelectric thin film 3 is patterned by photolithography and dry etching or wet etching, and finally the substrate 1 is cut into a size of 5 mm×20 mm, producing a plurality of thin film piezoelectric devices 10.

One of the resultant thin film piezoelectric devices 10 is cut, and a ratio of an area where a plurality of grains is present in a section is determined by the above-described method. In addition, the leakage current density between the electrode films and piezoelectric constant −d31 are measured using another one of the thin film piezoelectric devices 10. From a practical viewpoint, the thin film piezoelectric device 10 is required to have a leakage current density of 1×10⁻⁶ A/cm² or less, and −d31 of 70 pm/V or more.

### Embodiment 2

A sputtering target containing (K, Na)NbO₃ and Mn added as an additive in a range of 0.1 to 3.0 atomic % is used instead of the (K, Na)NbO₃ sputtering target used in Embodiment 1. A Mn adding amount of 3.0 atomic % or less tends to suppress a decrease in −d31 of the piezoelectric thin film 3 (KNN thin film), and a Mn adding amount of 0.1 atomic % or more tends to easily achieve the effect of decreasing the leakage current between the electrode films.

The substrate temperature is set to 520° C. to 480° C. At a substrate temperature of 520° C. or less, crystal growth is inhibited, resulting in a decrease in average crystal grain diameter of the piezoelectric thin film 3. At a set temperature of 480° C. or more, the average crystal grain diameter of the piezoelectric thin film 3 can be prevented from being excessively decreased, and deterioration in the piezoelectric constant −d31 can be prevented. The conditions other than the sputtering target and the substrate set temperature are the same as in Embodiment 1.

### Embodiment 3

A sputtering target further containing at least three additives selected from Li, Sr, Ba, Zr, Ta and added as additives is used instead of the sputtering target (K, Na)NbO₃ used in Embodiment 1. The ranges of amounts of the elements added are Li: 0.1 to 3.0 atomic %, Sr: 0.5 to 6.0 atomic %, Ba: 0.05 to 0.3 atomic %, Zr: 0.5 to 6.0 atomic %, and Ta: 0.01 to 15 atomic %. By setting the upper limit of the amount of each of the elements added to the above-described value, deterioration in the piezoelectric constant −d31 tends to be prevented. By setting the lower limit of the amount of each of the elements added to the above-described value, the piezoelectric constant −d31 tends to be improved. Instead of these elements, Mn may be added in the same range as in Embodiment 2.

The substrate temperature is set to 520° C. to 470° C. At a substrate temperature of 520° C. or less, crystal growth is inhibited, resulting in a decrease in average crystal grain diameter of the piezoelectric thin film 3 (KNN thin film). At a set temperature of 470° C. or more, the average crystal grain diameter of the piezoelectric thin film 3 can be prevented from being excessively decreased, and deterioration in the piezoelectric constant −d31 can be prevented. The conditions other than the sputtering target and the substrate set temperature are the same as in Embodiment 1.

### EXAMPLES

The present invention is described in further detail below based on examples and comparative examples, but the present invention is not limited to these examples.

### Example 1

A lower electrode film 2 was formed by crystal growth on a substrate 1 of single crystal Si to form an underlayer of a KNN thin film serving as a piezoelectric thin film 3. The lower electrode film 3 included a Pt film and had a thickness of 200 nm. The lower electrode film 3 was formed by the sputtering method under a condition in which the substrate was at 500° C.

Then, the KNN thin film was deposited using a (K, Na)NbO₃ sputtering target. The KNN film was formed by the sputtering method under a condition in which the substrate was at 520° C. The thickness of the KNN film was 2.0 μm.

In order to evaluate the average crystal grain diameter of the piezoelectric thin film 3, a surface of the piezoelectric thin film 3 was observed with SEM. A SEM image of the film surface was taken at an observation magnification of 5000 times, followed by image analysis. The diameter of each of the crystal grains was determined by approximating the shape as a circular shape. The average of the approximate diameters of the crystal grains was considered as the average crystal grain diameter. In this example, the average crystal grain diameter was 90 nm.

Next, Pt was deposited to form an upper electrode film 4. The same sputtering method as for the lower electrode film 2 was used as a formation method, but the substrate temperature was 200° C. The thickness of the film was 200 nm.

Next, a laminate including the piezoelectric thin film 3 was patterned by photolithography and dry etching or wet etching, and further the substrate was cut into a size of 5 mm×20 mm, producing a plurality of thin film piezoelectric devices 10.

The ratio of an area where a plurality of grains were present in the thickness direction of the piezoelectric thin film 3 was determined. In order to observe a section of the piezoelectric thin film 3, a portion of the thin film piezoelectric device 10 was cut in the thickness direction using FIB to form a cut surface. The cut surface was observed with TEM at an observation magnification of 1000 times to form a sectional image. Then, the total of areas of crystal grains in a portion where a plurality of grains were present in the thickness direction of the piezoelectric thin film 3 was determined and divided by the total area of the section within the observation range to calculate the ratio of an area where a plurality of grains were present in the thickness direction. The obtained ratio was 42%.

In addition, the piezoelectric characteristic −d31 of another thin film piezoelectric device 10 was evaluated. Voltages of 3 Vₚ₋ₚ and 20 Vₚ₋ₚ at 700 Hz were applied between the upper and lower electrode films of the thin film piezoelectric device 10, and a displacement at the tip of the thin film piezoelectric device 10 was measured with a laser Doppler vibrometer and an oscilloscope.

The piezoelectric constant −d31 was determined by calculation according to the following expression (1):

$${d}_{31} ≅ - \frac{{h}_{s}^{2}}{3 {L}^{2}} \frac{{s}_{11 , p}}{{s}_{11 , s}} \frac{δ}{V} \qquad Expression ( 1 )$$

hₛ: thickness of Si substrate [400 μm], S_{11,p}: elastic compliance of KNN thin film [1/104 GPa], S_{11,s}: elastic compliance of Si substrate [1/168 GPa], L: length of drive portion [13.5 mm], δ: displacement, V: applied voltage

The piezoelectric constant −d31 was 89 (pm/V) at 3 Vₚ₋ₚ and 89 (pm/V) at 20 Vₚ₋ₚ.

Table 1 shows the substrate temperature during deposition of the piezoelectric thin film 3, the film thickness, the average crystal grain diameter, the area ratio of deposited grains in the section to the total sectional area, the leakage current density, and the piezoelectric constant −d31 in Example 1.

### Examples 2 to 7 and Comparative Examples 1 to 3

A thin film piezoelectric device 10 was manufactured and evaluated with respect to the characteristics thereof in the same manner as in Example 1 except that the piezoelectric thin film 3 was formed at a substrate temperature shown in Table 1. The manufacture conditions and evaluation results are shown in Table 1.

### Examples 8 to 12 and Comparative Examples 4 and 5

A (K, Na)NbO₃ sputtering target containing 0.4 atomic % of Mn was used for forming the piezoelectric thin film 3, and the piezoelectric thin film 3 was formed at a substrate temperature shown in Table 1. Under the same other conditions as in Example 1, a thin film piezoelectric device 10 was manufactured, and the characteristics thereof were evaluated. The manufacture conditions and evaluation results are shown in Table 1.

### Examples 13 to 16 and Comparative Examples 6 and 7

A (K, Na)NbO₃ sputtering target containing 1.5 atomic % of Li, 0.1 atomic % of Ba, and 4 atomic % of Ta was used for forming the piezoelectric thin film 3, and the piezoelectric thin film 3 was formed at a substrate temperature shown in Table 1. Under the same other conditions as in Example 1, a thin film piezoelectric device 10 was manufactured, and the characteristics thereof were evaluated. The manufacture conditions and evaluation results are shown in Table 1.

### Examples 17 to 20 and Comparative Examples 8 and 9

A (K, Na)NbO₃ sputtering target containing 0.4 atomic of Mn, 1.5 atomic % of Li, 0.1 atomic % of Ba, and 4 atomic % of Ta was used for forming the piezoelectric thin film 3, and the piezoelectric thin film 3 was formed at a substrate temperature shown in Table 1. Under the same other conditions as in Example 1, a thin film piezoelectric device 10 was manufactured, and the characteristics thereof were evaluated. The manufacture conditions and evaluation results are shown in Table 1.

### Examples 21 to 24 and Comparative Examples 10 and 11

A (K, Na)NbO₃ sputtering target containing 0.4 atomic % of Mn, 1.5 atomic % of Li, 3.0 atomic % of Sr, 0.1 atomic % of Ba, 3.0 atomic % of Zr, and 4 atomic % of Ta was used for forming the piezoelectric thin film 3, and the piezoelectric thin film 3 was formed at a substrate temperature shown in Table 1. Under the same other conditions as in Example 1, a thin film piezoelectric device 10 was manufactured, and the characteristics thereof were evaluated. The manufacture conditions and evaluation results are shown in Table 1.

It was confirmed that the thin film piezoelectric devices 10 of Examples 1 to 24 each including the KNN thin film having an average crystal grain diameter of 60 nm or more and 90 nm or less and the pair of electrode films formed to hold the KNN thin film therebetween have larger piezoelectric constants −d31 at 20 Vₚ₋ₚ than in Comparative Examples 1 to 11 having an average crystal grain diameter out of the range. This is realized by providing the thin film piezoelectric devices 10 of Examples 1 to 24 with both the characteristic of a leakage current density of 1.0×10⁻⁶ A/cm² or less, which is minimum required for practical application, and the piezoelectric characteristics which can be secured by controlling the average crystal grain diameter to 60 nm or more and 90 nm or less. In Comparative Example 1 having a larger piezoelectric constant −d31 at 3 Vₚ₋ₚ, the piezoelectric constant −d31 at 20 Vₚ₋ₚ is low because the piezoelectric constant −d31 cannot be normally measured at 20 Vₚ₋ₚ due to a high leakage current density.

It was also confirmed that the thin film piezoelectric devices 10 of Examples 2 to 24 each including the KNN thin film having an average crystal grain diameter of 60 nm or more and 90 nm or less and having a deposited grain area ratio of 50% or more in the section exhibit lower leakage current densities than that of the thin film piezoelectric device 10 of Example 1 including the KNN thin film having an average crystal grain diameter of 60 nm or more and 90 nm or less but having a deposited grain area ratio of 50% or less in the section.

Comparing the leakage current densities of the thin film piezoelectric devices 10 of Examples 8 to 12 each including the KNN thin film having an average crystal grain diameter of 60 nm or more and 90 nm or less and containing Mn with the leakage current densities of the thin film piezoelectric devices 10 of Examples 1 to 7 each including the KNN thin film having substantially the same average crystal grain diameter (±5%) as in Examples 8 to 12 but not containing Mn, it was confirmed that the thin film piezoelectric devices 10 of Examples 8 to 12 have lower leakage current densities.

It was further confirmed that the thin film piezoelectric devices 10 of Examples 13 to 16 each including the KNN thin film having an average crystal grain diameter of 60 nm or more and 90 nm or less and containing three elements selected from Li, Ba, Ta, Sr, and Zr exhibit higher piezoelectric constants −d31 than those of the thin film piezoelectric devices 10 of Examples 1 to 12 not containing these elements.

It was further confirmed that the thin film piezoelectric devices 10 of Examples 17 to 20 each including the KNN thin film having an average crystal grain diameter of 60 nm or more and 90 nm or less and containing Mn, Li, Ba, and Ta exhibit lower leakage current densities than those of the thin film piezoelectric devices 10 of Examples 13 to 16 each including the KNN thin film containing only Li, Ba, and Ta but not Mn (comparison between the KNN thin films having substantially the same average crystal grain diameter (±5%)). In addition, it was confirmed that Examples 17 to 20 have higher piezoelectric constants −d31.

It was further confirmed that the thin film piezoelectric devices 10 of Examples 21 to 24 each including the KNN thin film having an average crystal grain diameter of 60 nm or more and 90 nm or less and containing Mn, Li, Ba, Ta, Sr, and Zr exhibit higher piezoelectric constants −d31 than those of the thin film piezoelectric devices 10 of Examples 17 to 20 each including the KNN thin film having an average crystal grain diameter of 60 nm or more and 90 nm or less and containing Mn, Li, Ba, and Ta. [Table 1]

TABLE 1

| | | | | Average | Area | | | |
|---|---|---|---|---|---|---|---|---|
| | | | KNN | crystal | ratio of | Leakage | | |
| | | Substrate | film | grain | deposited grains | current | | |
| | | temperature | thickness | diameter | in section | density | −d31 (pm/V) | |
| | Additive | (° C.) | (um) | (nm) | (%) | (A/cm²) | Vₚ₋ₚ3 V | Vₚₚ20 V |
| Comparative | No | 550 | 2.0 | 320 | 4 | 2.4 × 10⁻² | 101 | 0 |
| Example 1 | | | | | | | | |
| Comparative | No | 530 | 2.0 | 95 | 40 | 7.4 × 10⁻⁴ | 92 | 3 |
| Example 2 | | | | | | | | |
| Example 1 | No | 520 | 2.0 | 90 | 42 | 9.9 × 10⁻⁷ | 89 | 89 |
| Example 2 | No | 510 | 2.0 | 86 | 55 | 6.0 × 10⁻⁷ | 86 | 86 |
| Example 3 | No | 500 | 2.0 | 83 | 60 | 4.5 × 10⁻⁷ | 81 | 81 |
| Example 4 | No | 490 | 2.0 | 77 | 66 | 3.8 × 10⁻⁷ | 79 | 79 |
| Example 5 | No | 480 | 2.0 | 71 | 67 | 3.0 × 10⁻⁷ | 77 | 77 |
| Example 6 | No | 470 | 2.0 | 65 | 70 | 8.0 × 10⁻⁸ | 73 | 73 |
| Example 7 | No | 460 | 2.0 | 61 | 81 | 7.2 × 10⁻⁸ | 70 | 70 |
| Comparative | No | 450 | 2.0 | 55 | 87 | 3.2 × 10⁻⁸ | 26 | 26 |
| Example 3 | | | | | | | | |
| Comparative | Mn | 530 | 2.0 | 92 | 42 | 7.5 × 10⁻⁹ | 90 | 10 |
| Example 4 | | | | | | | | |
| Example 8 | Mn | 520 | 2.0 | 87 | 54 | 7.1 × 10⁻⁸ | 82 | 82 |
| Example 9 | Mn | 510 | 2.0 | 79 | 56 | 6.9 × 10⁻⁸ | 77 | 77 |
| Example 10 | Mn | 500 | 2.0 | 75 | 60 | 6.7 × 10⁻⁸ | 73 | 73 |
| Example 11 | Mn | 490 | 2.0 | 72 | 71 | 2.0 × 10⁻⁸ | 71 | 71 |
| Example 12 | Mn | 489 | 2.0 | 65 | 74 | 1.1 × 10⁻⁸ | 70 | 70 |
| Comparative | Mn | 470 | 2.0 | 58 | 80 | 5.0 × 10⁻⁹ | 30 | 30 |
| Example 5 | | | | | | | | |
| Comparative | Li, Ba, Ta | 530 | 2.0 | 93 | 45 | 2.5 × 10⁻⁵ | 102 | 28 |
| Example 6 | | | | | | | | |
| Example 13 | Li, Ba, Ta | 520 | 2.0 | 88 | 58 | 8.0 × 10⁻⁷ | 96 | 96 |
| Example 14 | Li, Ba, Ta | 490 | 2.0 | 80 | 62 | 5.5 × 10⁻⁷ | 92 | 92 |
| Example 15 | Li, Ba, Ta | 480 | 2.0 | 72 | 71 | 1.1 × 10⁻⁷ | 88 | 88 |
| Example 16 | Li, Ba, Ta | 470 | 2.0 | 62 | 84 | 2.5 × 10⁻⁸ | 80 | 80 |
| Comparative | Li, Ba, Ta | 460 | 2.0 | 57 | 90 | 1.0 × 10⁻⁸ | 38 | 38 |
| Example 7 | | | | | | | | |
| Comparative | Mn, Li, Ba, Ta | 530 | 2.0 | 92 | 48 | 4.5 × 10⁻⁸ | 110 | 39 |
| Example 8 | | | | | | | | |
| Example 17 | Mn, Li, Ba, Ta | 520 | 2.0 | 86 | 59 | 6.2 × 10⁻⁸ | 100 | 100 |
| Example 18 | Mn, Li, Ba, Ta | 490 | 2.0 | 78 | 63 | 5.2 × 10⁻⁸ | 98 | 98 |
| Example 19 | Mn, Li, Ba, Ta | 480 | 2.0 | 71 | 74 | 1.0 × 10⁻⁸ | 95 | 95 |
| Example 20 | Mn, Li, Ba, Ta | 470 | 2.0 | 62 | 88 | 8.0 × 10⁻⁹ | 89 | 89 |
| Comparative | Mn, Li, Ba, Ta | 460 | 2.0 | 55 | 95 | 4.0 × 10⁻⁸ | 40 | 40 |
| Example 9 | | | | | | | | |
| Comparative | Mn, Li, Sr, Ba, Zr, Ta | 530 | 2.0 | 91 | 49 | 4.0 × 10⁻⁸ | 121 | 44 |
| Example 10 | | | | | | | | |
| Example 21 | Mn, Li, Sr, Ba, Zr, Ta | 520 | 2.0 | 84 | 60 | 6.4 × 10⁻⁸ | 110 | 110 |
| Example 22 | Mn, Li, Sr, Ba, Zr, Ta | 490 | 2.0 | 76 | 64 | 5.0 × 10⁻⁸ | 108 | 108 |
| Example 23 | Mn, Li, Sr, Ba, Zr, Ta | 480 | 2.0 | 70 | 75 | 9.0 × 10⁻⁹ | 102 | 102 |
| Example 24 | Mn, Li, Sr, Ba, Zr, Ta | 470 | 2.0 | 60 | 90 | 7.3 × 10⁻⁹ | 99 | 99 |
| Comparative | Mn, Li, Sr, Ba, Zr, Ta | 460 | 2.0 | 53 | 98 | 3.0 × 10⁻⁹ | 45 | 45 |
| Example 10 | | | | | | | | |

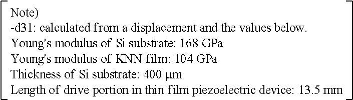

1. A thin film piezoelectric device comprising a potassium sodium niobate-based piezoelectric thin film which has an average crystal grain diameter of 60 nm or more and 90 nm or less, and a pair of electrode films configured to hold the piezoelectric thin film therebetween.

2. The thin film piezoelectric device according to claim 1, wherein a sectional structure of the piezoelectric thin film in a direction perpendicular to the electrode films contains a portion where a plurality of grains are present in the thickness direction of the piezoelectric thin film, and a ratio of total sectional area of grains constituting the portion where the plurality of grains are present is 50% or more of a total sectional area of the piezoelectric thin film.

3. The thin film piezoelectric device according to claim 1, wherein the piezoelectric thin film contains Mn (manganese).

4. The thin film piezoelectric device according to claim 1, wherein the piezoelectric thin film contains at least three elements selected from Li (lithium), Sr (strontium), Ba (barium), Zr (zirconium), and Ta (tantalum).
